(19) United States
(12) Patent Application Publication
(10) Pub. No.: US 2006/0203310 A1
(43) Pub. Date: Sep. 14, 2006

(54) Exposure head controller and image formation device

(75) Inventors: Kenji Yamaguchi, Nagano-ken (JP); Mitsukazu Kurose, Nagano-ken (JP); Nozomu Inoue, Nagano-ken (JP); Ken Ikuma, Nagano-ken (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 11/370,382

(22) Filed: Mar. 2, 2006

(30) Foreign Application Priority Data
Mar. 14, 2005 (JP) 2005-071393

(51) Int. Cl. G03F 3/08

(52) U.S. Cl. 358/509; 358/521

(57) ABSTRACT

Provided is an exposure head controller for controlling a plurality of light-emitting elements arranged in a first direction and exposing a plurality of pixels, including: an exposure data generator for generating, based on pixel exposure data for exposing the respective pixels, a plurality of area exposure data for respectively exposing a plurality of areas in which the respective pixels are divided in a second direction intersecting with the first direction; and an exposure controller for exposing the plurality of pixels by controlling the plurality of light-emitting elements and exposing the plurality of areas based on the area exposure data.

### CROSS-REFERENCES

The entire disclosure of Japanese Patent Application No. 2005-71393 filed on Mar. 14, 2005 including specification, claims, drawings and summary are incorporated herein by reference in its entirety.

### BACKGROUND

1. Technical Field

The present invention pertains to an exposure head controller and an image formation device including such an exposure head controller.

2. Related Art

JP-A-2002-248808 discloses a conventional image formation device having an LED print head. The conventional image formation device disclosed in JP-A-2002-248808 changes, in accordance with the gradation of image data, the cycle of the lighting reference clock for changing the lighting time of the LED according to the gradation of image data.

With this kind of conventional image formation device, when attempting to control the exposure position of each LED, the lighting timing must be controlled individually for all LEDs. In other words, with the foregoing conventional image formation device, since a circuit for controlling the lighting timing of LEDs must be provided to each LED, there is a problem in that the circuit becomes complex.

### SUMMARY

The exposure head controller according to the present invention is an exposure head controller for controlling a plurality of light-emitting elements arranged in a first direction and exposing a plurality of pixels, including: an exposure data generator for generating, based on pixel exposure data for exposing the respective pixels, a plurality of area exposure data for respectively exposing a plurality of areas in which the respective pixels are divided in a second direction intersecting with the first direction; and an exposure controller for exposing the plurality of pixels by controlling the plurality of light-emitting elements and exposing the plurality of areas based on the area exposure data.

The image formation device according to the invention includes the foregoing exposure head controller.

### BRIEF DESCRIPTION OF THE DRAWINGS

FIG. 1 is a diagram showing an example of the configuration of the image formation device 100;

FIG. 2 is a diagram showing an example of the configuration of the line head 140;

FIG. 3A to FIG. 3C are diagrams showing an example of the data organization of the gradation value LUT 126;

FIG. 4 is a diagram showing the setting method of the gradation value of areas configuring the pixels;

FIG. 5 is a timing chart showing the operation of the image formation device;

FIG. 6 is a view showing a frame format of the status of dots exposed with the image formation device of this embodiment;

FIG. 7 is a view showing a frame format of the status of dots exposed with the comparative example;

FIG. 8A to FIG. 8C are diagrams showing another example of the data organization of the gradation value LUT 126; and

FIG. 9 is a diagram showing the setting method of the gradation value of areas configuring the pixels.

### DESCRIPTION OF EXEMPLARY EMBODIMENTS

An object of an embodiment of the present invention is to provide an exposure head controller and image formation device capable of overcoming the foregoing problems.

According to an aspect of the invention, provided is an exposure head controller for controlling a plurality of light-emitting elements arranged in a first direction and exposing a plurality of pixels, including: an exposure data generator for generating, based on pixel exposure data for exposing the respective pixels, a plurality of area exposure data for respectively exposing a plurality of areas in which the respective pixels are divided in a second direction intersecting with the first direction; and an exposure controller for exposing the plurality of pixels by controlling the plurality of light-emitting elements and exposing the plurality of areas based on the area exposure data.

According to the foregoing configuration, since the respective pixels are divided into a plurality of areas and exposed based on pixel exposure data, the dot position to be exposed in the respective pixels can be controlled. Accordingly, with the foregoing configuration, for instance, high-quality images can be formed since it will be possible to perform processing for smoothing the shaded portions and curved portions to the image to be formed.

With the foregoing exposure head controller, it is preferable that the pixel exposure data contains pixel gradation data showing the gradation of pixels; the exposure data generator generates area gradation data showing the gradation of the respective areas as the area exposure data based on the pixel gradation data; and the exposure controller controls the gradation of the plurality of areas based on the area gradation data.

According to the foregoing configuration, an even higher quality image can be formed since the gradation of dots can be controlled in addition to the dot position in the respective pixels.

With the foregoing exposure head controller, it is preferable that the exposure data generator generates the area gradation data further based on dot position data showing the position of dots to be exposed in the respective pixels. Here, the exposure data generator, for example, generates area exposure data such as by sorting the gradation values showing the pixel exposure data respectively to the plurality of areas based on exposure area data.

With the foregoing exposure head controller, it is preferable that the exposure data generator has a gradation value table that associates and stores the pixel exposure data and the area exposure data.

With the foregoing configuration, since the exposure data generator is able to read area exposure data from the gradation value table based on pixel exposure data, gradation control can be performed at extremely high speed. For example, pixel exposure data is preferably configured from a plurality of bit counts so as to show a prescribed address of the gradation value table.

According to another aspect of the invention, provided is an image formation device including the foregoing exposure head controller. The image formation device, for instance, is a printing device such as a laser printer.

The invention is now explained based on embodiments with reference to the drawings. Nevertheless, the following embodiments do not limit the scope of claims in the invention, and all combinations of the features explained in the embodiments are not necessarily required as means for solving the foregoing problems.

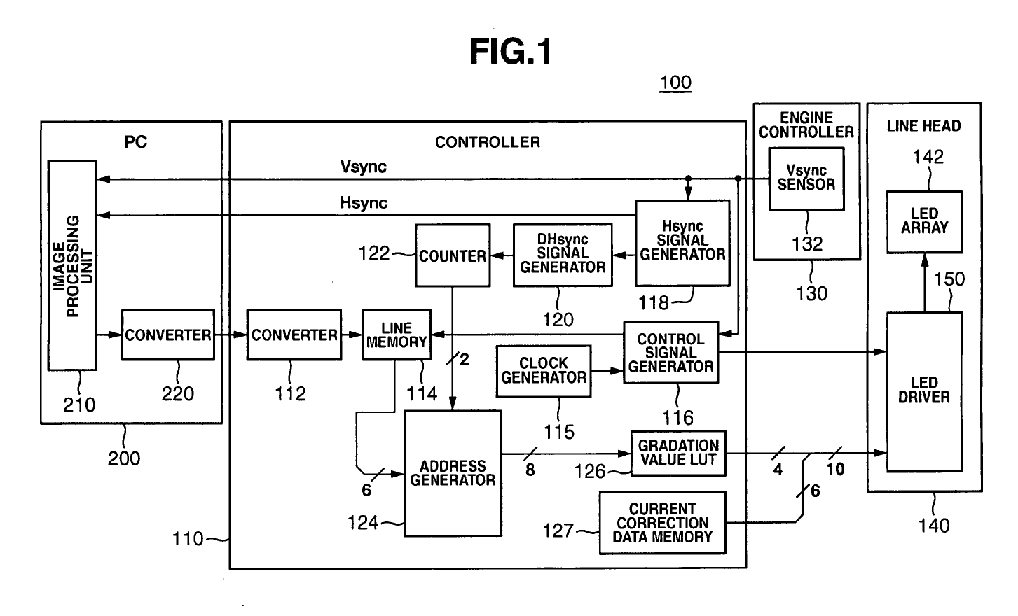

FIG. 1 is a diagram showing an example of the configuration of an image formation device 100. The image formation device 100 is configured from a controller 110 as an example of an exposure head controller, an engine controller 130 for controlling the engine, and a line head 140.

The controller 110 is configured from a converter 112, a line memory 114, a clock generator 115, a control signal generator 116, an Hsync signal generator 118, a DHsync signal generator 120, a counter 122, an address generator 124, a gradation value lookup table (LUT) 126, and a current correction data memory 127. The address generator 124 and gradation value LUT 126 are examples of an exposure data generator.

The converter 112 receives pixel exposure data (serial data) for exposing the respective pixels output from a personal computer (PC) 200, converts this into parallel data (6 bit), and supplies this to the line memory 114. The pixel exposure data of this embodiment is configured by containing pixel gradation data showing the gradation of the respective pixels, and dot position data showing the position to which the dots are to be gathered in the respective pixels.

The clock generator 115 generates a clock signal CLK to become the reference of operation of the controller 110, and supplies this to the control signal generator 116. The control signal generator 116 receives the clock signal CLK and printing start signal Vsync, creates an Sclock signal SCLK and strobe signal STB, and supplies these to the LED driver 150. Further, the control signal generator 116, based on the clock signal CLK, creates a read/write enable signal RWE and supplies this to the line memory 114.

The line memory 114 stores pixel exposure data for each line, and supplies pixel exposure data to the address generator 124 based on the read/write enable signal RWE supplied from the control signal generator 116.

Hsync signal generator 118, based on the printing start signal Vsync generated by the Vsync sensor 132, generates a transmission start signal Hsync of exposure data, and supplies this to the PC 200 and DHsync signal generator 120. The DHsync signal generator 120 receives the transmission start signal Hsync, and creates a DHsync signal by multiplying [the transmission start signal Hsync]. In this embodiment, the DHsync signal generator 120 creates the DHsync signal by multiplying the cycle of the transmission start signal Hsync three times.

The counter 122 supplies count data counted based on the DHsync signal to the address generator 124. The bit count of the counter 122 is set by the DHsync signal generator 120 based on the frequency dividing ratio of the transmission start signal Hsync. In this embodiment, since the DHsync signal generator 120 multiplies the transmission start signal Hsync three times, the counter 122 is configured such that the bit count thereof is set to 2 bit, and reset every 3 counts.

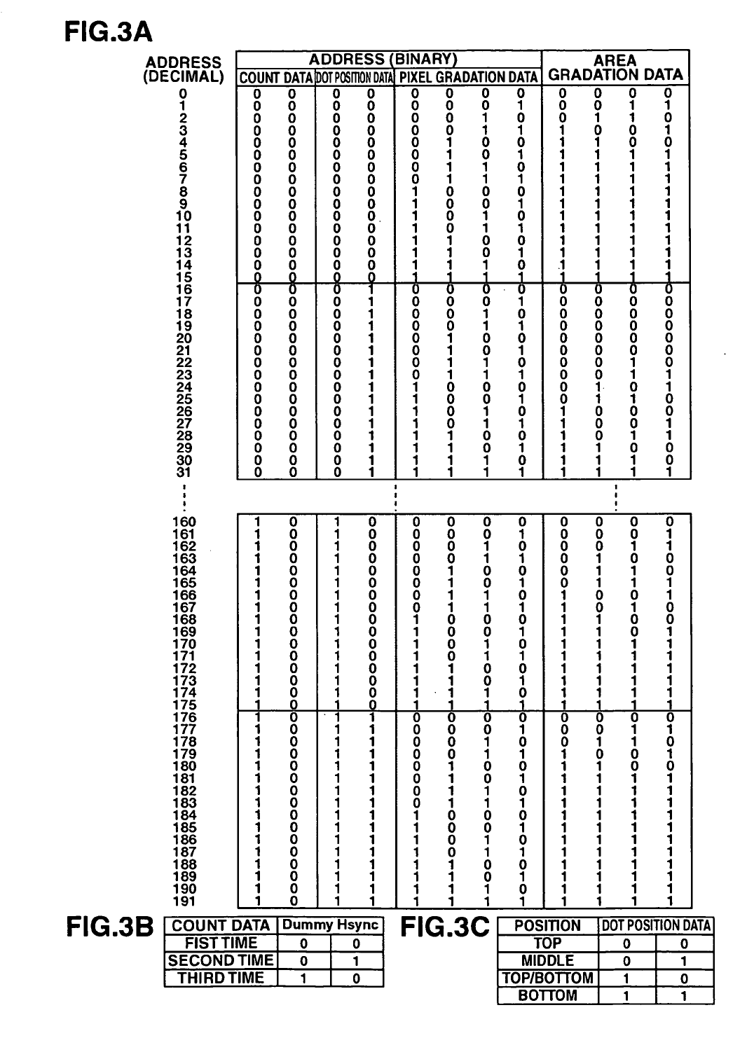

The address generator 124, based on pixel exposure data and count data, generates an address signal designating an address storing area gradation data in the gradation value LUT 126. Specifically, the address generator 124 generates a plurality of address signals by sequentially adding count data to prescribed pixel exposure data supplied from the line memory 114. And when the count data is reset, the address generator 124 generates a plurality of address data by sequentially adding new count data to another pixel exposure data. In other words, in this embodiment, the address generator 124 generates three address signals by respectively adding three count data to one pixel exposure data. Specific examples of the bit configuration of the address signal will be described later with reference to FIG. 3A to FIG. 3C.

The gradation value LUT 126 stores area gradation data showing the gradation of the respective areas configuring the pixels upon associating it with the address. When the gradation value LUT 126 receives an address signal from the address generator 124, it outputs area gradation data corresponding to such address to the line head 140.

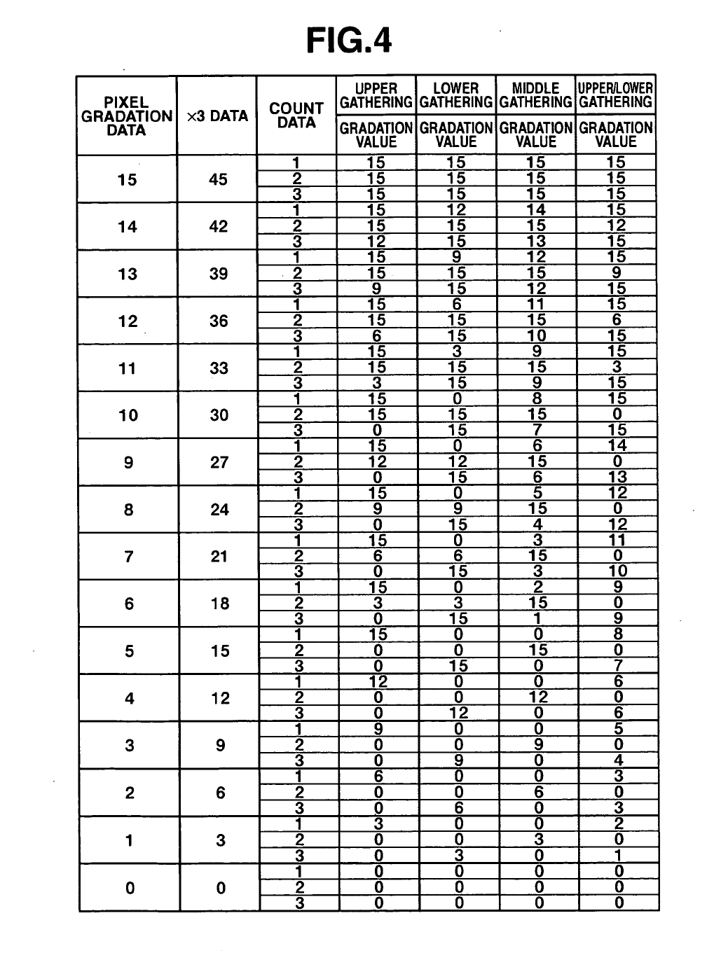

In this embodiment, area gradation data is data showing the gradation of an area that is ⅓ of the respective pixels. In other words, pixel exposure data for exposing a certain pixel is converted into three address data to which count data is added for exposing the pixel upon dividing it into three areas in the address generator 124. Then, the three address data are converted into area gradation value data for respectively exposing the divided three areas in the gradation value LUT 126. The relationship of pixel exposure data and area gradation data is described later with reference to FIG. 3A to FIG. 3C and FIG. 4.

The current correction data memory 127 stores current correction data for correcting the current magnitude to be supplied to the LED array 142. In this embodiment, the current correction data memory 127 stores current correction data unique to the line head 140 attributable to variations in the manufacture process or the like, and is configured to constantly supply this to the line head 140. In this embodiment, area gradation data (4 bit) output from the gradation value LUT 126 and current correction data (6 bit) output from the current correction data memory 127 are supplied to the LED driver 150 as 10 bit data signal DATA.

The engine controller 130 is configured by including a Vsync sensor 132, recognizes the edge or the like of the medium to which the image is to be formed, creates a printing start signal Vsync based thereon, and supplies this to the controller 110 and PC 200.

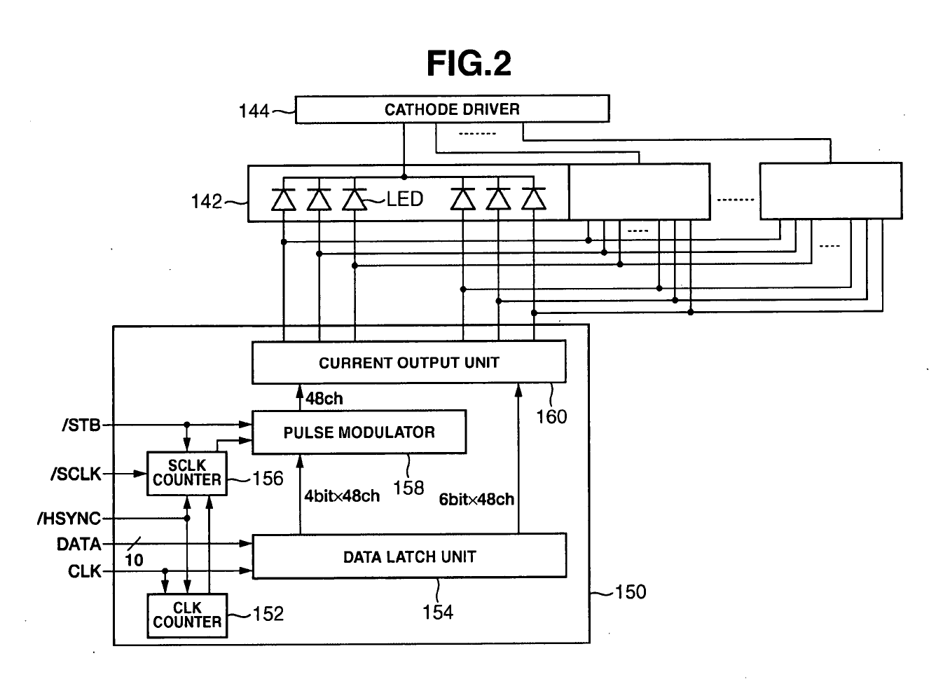

FIG. 2 is a diagram showing an example of the configuration of the line head 140. The line head 140 is configured by including an LED array 142, a cathode driver 144 and an LED driver 150. With the line head 140 of this embodiment, the configuration shown in FIG. 2 is disposed in a plurality so that the number of LED arrays 142 becomes 56 arrays. Further, each LED array 142 has 48 LEDs arranged in a primary scanning direction which is an example of the first direction, and each LED exposes the respective pixels. Incidentally, the number of LED arrays 142 to be provided to the line head 140 and the number of LEDs in the respective LED arrays 142 are arbitrary.

The cathode driver 144 is connected to a cathode of the LED configuring the respective LED arrays 142, and the cathode of each LED is sequentially grounded in LED array 142 units. Further, the LED driver 150 supplies current to the LED array 142 in accordance with the operation of the cathode driver 144 grounding the LED array 142, and thereby illuminates the LED array. In other words, in this embodiment, the LED driver 150 and cathode driver 144 sequentially illuminate 56 LED arrays 142 and expose the respective pixels.

The LED driver 150 is an example of the exposure controller, and is configured by including a CLK counter 152, a data latch unit 154, an SCLK counter 156, a pulse modulator 158, and a current output unit 160. The LED driver 150 of this embodiment controls the illumination time and illumination timing of the LED array 142 based on the signal/STB, /SCLK, /Hsync, CLK and DATA supplied from the control signal generator 116.

The CLK counter 152 counts the edges of the clock signal CLK supplied from the control signal generator 116. In this embodiment, the CLK counter 152 starts counting according to the edge of the transmission start signal/Hsync, and resets the SCLK counter 156 when the count value becomes 48, which is the number of LEDs provided to the LED array 142.

The data latch unit 154 is configured by including 48 shift registers and latches, which is the number of LEDs configuring the LED array 142. The data latch unit 154 sequentially shifts the data signal DATA and retains this in the respective latches according to the change in the edge of the clock signal CLK. Further, the data latch unit 154 supplies area gradation data (4 bit) to the pulse modulator 158 among the retained data signal DATA, and supplies current correction data (6 bit) to the current output unit 160.

The SCLK counter 156 counts the edges of the Sclock signal SCLK. The SCLK counter 156 is reset in accordance with the transmission start signal/Hsync and the edge of the signal output from the CLK counter 152, and starts counting according to the edge of the signal/STB.

The pulse modulator 158 is configured by including 48 comparators, and controls the current output unit 160 so as to control the illumination time of the 48 LEDs provided to the respective LED arrays 142. Specifically, the pulse modulator 158, according to the edge of the signal/STB, controls the current output unit 160 so that the 48 LEDs will start illuminating. Further, in the pulse modulator 158, each comparator receives the count value from the SCLK counter, and receives area gradation data from the corresponding latch of the data latch unit 154. And, each comparator controls the current output unit 160 so as to stop the illumination of the corresponding LEDs when the received count value coincides with the area gradation data. In other words, the 48 LEDs start illuminating at roughly the same time, and stop illuminating at a timing according to the value of the area gradation data corresponding to the respective LEDs. Thereby, the illumination time of each LED is controlled, and gradation of the dot to be exposed in the respective pixels is controlled.

The current output unit 160 supplies prescribed current to each LED of the LED array 142 according to the control from the pulse modulator 158. Specifically, the current output unit 160 starts supplying prescribed current at roughly the same timing to each LED, and stops the supply of prescribed current to each LED according to the time each LED is to be illuminated. Further, the current output unit 160 corrects the current magnitude to be supplied to each LED based on the current correction data supplied from the data latch unit 154.

FIG. 3A to FIG. 3C are diagrams showing an example of the data organization of the gradation value LUT 126. As shown in FIG. 3A, the gradation value LUT 126 associates and stores the address showing the address signal and area gradation data. The address (10 bit) is configured from 2 bit count data, and pixel exposure data including 2 bit dot position data and 4 bit gradation data. Incidentally, area gradation data is generated based on pixel gradation data and dot position data, and is pre-stored in the gradation value LUT 126.

FIG. 3B is a diagram showing the relationship of count data (output value of the counter 122) and bit value. In this embodiment, by adding count data (1 to 3 times) to pixel exposure data, the pixel to be exposed is divided into three areas, and gradation data is respectively assigned to each area. Specifically, “first time”, “second time” and “third time” respectively show the areas to be exposed the first time, second and third time among the three areas in which the pixel was divided.

FIG. 3C is a diagram showing the relationship of dot position data and bit value. “Upper gathering” means to gather the dots to be exposed at the upper part by performing the processing of this embodiment in comparison to a case where such processing is not performed. Further, “middle gathering”, “upper/lower gathering” and “lower gathering” similarly show that the dots are to be gathered in the middle part, upper/lower part and lower part. In this embodiment, dot position data configures a part of pixel exposure data, and is supplied as pixel exposure data from the PC 200 to the controller 110.

FIG. 4 is a diagram showing the setting method of gradation value of the area configuring the pixels. The pixel gradation value showing pixel gradation data is 16 shades of gray (4 bit in binary digit), and triple data in which data of such 16 shades of gray multiplied three times is generated. Then, by allocating the triple data value to the three areas in which the pixels were divided based on the dot position (i.e., dot position data) to be exposed in the respective pixels, the area gradation value in each area is set.

For example, when the pixels gradation value is “12” and “upper gathering” is to be performed, the area gradation value of the three areas configuring the pixel is numbered “15”, “15” and “6” from the top, and, by exposing the upper area of pixels stronger than the lower area of pixels, the dots to be exposed by the pixels can be gathered upward as a whole.

And, by associating each area gradation value as 4 bit data with the address (i.e.; count data, dot position data and pixel gradation data), the LUT is created thereby.

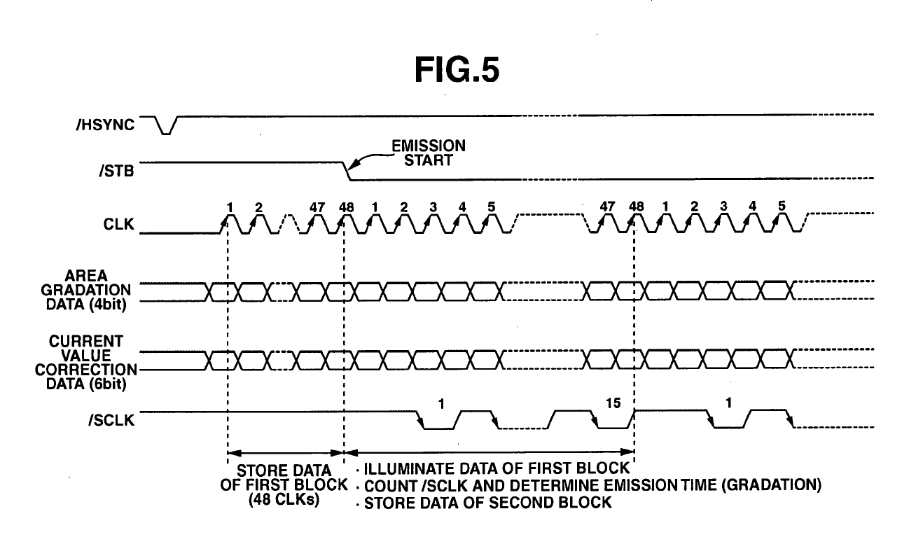

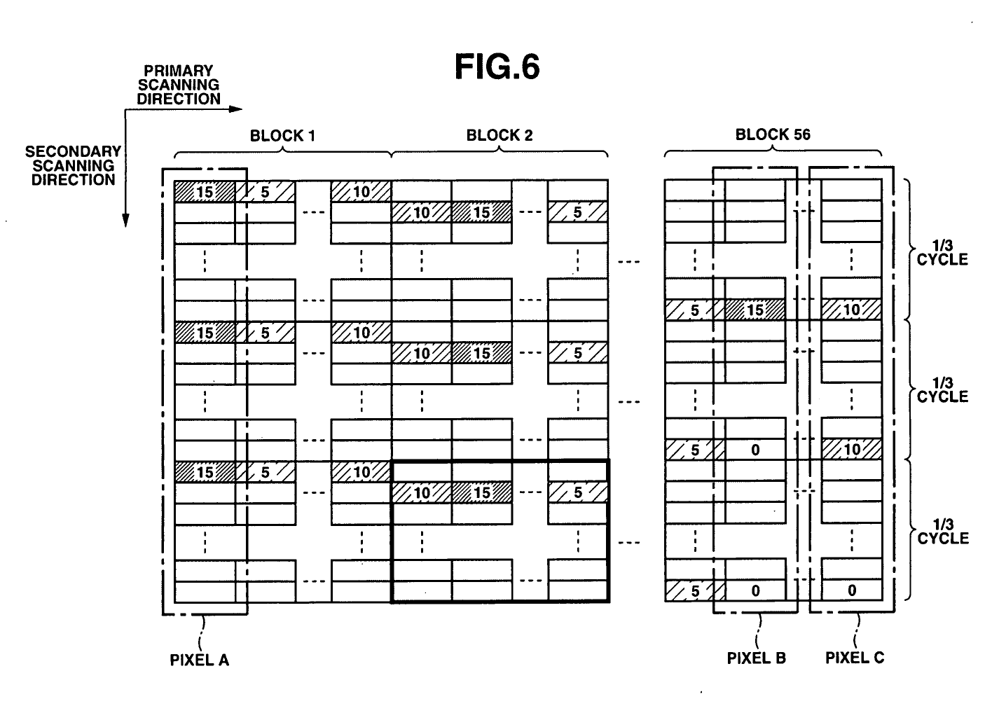

FIG. 5 is a timing chart showing the operation of the image formation device. Operation of the image formation device 100 of this embodiment is now explained with reference to FIG. 1, FIG. 3A to FIG. 3C and FIG. 5. In the following example, 1 line is divided into 56 block formed from 48 pixels (refer to FIG. 6), and the controller 110 supplies data to the LED driver 150 in block units (i.e., 48 pixels worth), and the LED driver 150 illuminates the LED in LED array 142 units so as to expose the pixels in block units. In other words, the image formation device of this embodiment forms images on a medium by exposing the 56 blocks in time division.

Foremost, operation of the controller 110 supplying signals and data required for exposure to the LED driver 150 is explained, and, subsequently, operation of the LED driver 150 illuminating the LED array 142 based on such signals and data is explained.

Foremost, in the engine controller 130, the Vsync sensor 132 detects the top of the medium to which image is to be formed, and changes the logical value of the printing start signal Vsync. Further, when the Hsync signal generator 120 detects a change in the logical value of the printing start signal Vsync, it generates a transmission start signal Hsync, and supplies this to the image processing unit 210 and DHsync signal generator 120 of the PC 200. The transmission start signal Hsync is a signal in which a pulse appears in a prescribed cycle, and, when the image processing unit 210 detects each pulse (edge), it starts transmitting 1 line worth of pixel exposure data (raster data).

The pixel exposure data transmitted from the image processing unit 210 is accumulated in the line memory 114 via the converters 220 and 112. Each pixel exposure data accumulated in the line memory 114 is sequentially supplied to the address generator 124 according to the read/write enable signal RWE supplied from the control signal generator 116.

Meanwhile, the counter 122 counts the count data based on the DHsync signal obtained by multiplying the transmission start signal Hsync three times, and supplies this to the address generator 124. In other words, the counter 122 repeatedly supplies to the address generator 124 2 bit data (count data) of “00”, “01” and “10” during one cycle of the transmission start signal Hsync. Then, the address generator 124 generates three addresses in which three count data were combined with one pixel exposure data, and sequentially supplies this to the gradation value LUT 126. The gradation value LUT 126, according to the address showing the address signal, supplies the stored area gradation data to the LED driver 150. Thereby, area gradation data is supplied from the gradation value LUT 126 to the LED driver 150 according to the pixel exposure data transmitted from the PC 200.

Next, operation of the LED driver 150 illuminating the respective LEDs of the LED array 142 is explained.

Foremost, when the logical value of the transmission start signal/Hsync is changed, the control signal generator 116 supplies a clock signal CLK to the CLK counter 152 and data latch unit 154. Then, the data latch unit 154 foremost receives from the controller 110 data to be supplied to the LED array 142 (first block (refer to FIG. 6)) to be illuminated first among the 56 LED arrays 142, and retains the same. Specifically, the data latch unit 154 sequentially receives area gradation data and current correction data (data signal DATA) for illuminating the 48 LEDs according to changes in the edge of the clock signal CLK, sequentially shifts the data in the 48 shift registers, and stores this in the latch corresponding to each shift register.

When the data latch unit 154 stores all area gradation data and current correction data of the first block, the signal/STB changes from H logic to L logic, and the LED array 142 of the first block starts to illuminate. Specifically, when the signal/STB changes to L logic, the pulse modulator 158 controls the current output unit 160 so that prescribed current is supplied respectively so as to illuminate the 48 LEDs. The current output unit 160 supplies prescribed current and illuminates the 48 LEDs based on the current correction data supplied from the data latch unit 154.

Further, when the signal/STB changes from H logic to L logic, the SCLK counter 156 is reset, and the SCLK counter 156 supplies to the pulse modulator 158 the count value counted based on the signal/SCLK supplied from the control signal generator 126.

The pulse modulator 158 respectively compares the count value of the SCLK counter 156 and area gradation data of the 48 LEDs supplied from the data latch unit 154. And, when the count value and area gradation data coincide, the pulse modulator 158 controls the current output unit 160 so as to stop the illumination of the LED corresponding to the coinciding area gradation data. In this embodiment, since the area gradation data is 4 bit data, area gradation data corresponding to the 48 LEDs will coincide with the count value before the count value of the SCLK counter 156 reaches “15” so as to stop the illumination of all LEDs of the first block.

Moreover, since the data latch unit 154 illuminates the LEDs of the second block during the period when the pulse modulator 158 is illuminating the LEDs of the first block, it receives data signal DATA. Specifically, the data latch unit 154, during the period that the pulse modulator 158 and current output unit 160 are illuminating the LEDs of the first block according to the edge of the signal/SCLK, shifts area gradation data and current correction data for illuminating the LEDs of the second block according to the edge of the clock signal CLK in the 48 shift registers, and retains this in the 48 latches.

And, when the reception of area gradation data and current correction data of the second block is complete, the data latch unit 154 supplies these to the pulse modulator 158, and starts the reception of area gradation data and current correction data of the third block. Meanwhile, the pulse modulator 158 and current output unit 160, during the period the pulse modulator 158 is receiving data of the third block, controls the illumination of LEDs of the second block based on area gradation data and current correction data of the second block. By repeating the foregoing operation, the LED arrays 142 of 56 blocks are illuminated and one line worth of image is formed on the medium.

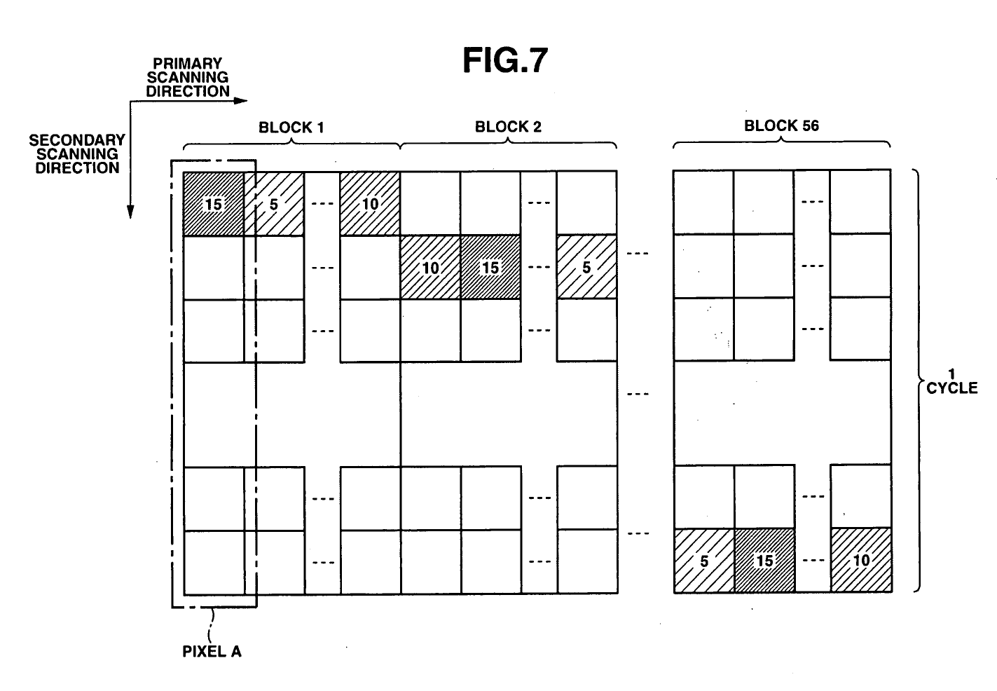

FIG. 6 is a view showing a frame format of a state of the dots exposed in the respective pixels in a case where the image formation device of this embodiment divided the pixel into three areas and exposed one line at ⅓ cycle of the Hsync signal. FIG. 7 is a view showing a frame format of a state of the dots exposed in the respective pixels in a case where the image formation device (comparative example) that does not perform the processing of this embodiment exposed one line at 1 cycle of the Hsync signal. Both FIG. 6 and FIG. 7 illustrate results upon exposing block 1 to block 56 in order in time division upon exposing one line worth of pixels.

As shown in FIG. 7, when 56 blocks worth of pixels are exposed with the comparative example, displacement of roughly one cycle worth of the Hsync signal will occur between the dot in block 1 that was exposed first and the dot in block 56 that was exposed last in the secondary scanning direction. Meanwhile, as shown in FIG. 6, with the image formation device of this embodiment, since the pixels divided for each ⅓ cycle and exposed, displacement of roughly ⅓ cycle will only occur, and it is thereby possible to form a high quality image on the medium.

Further, as shown in FIG. 7, with the comparative example, since the dot position in the secondary scanning direction in the pixel is set forth based on the exposure order of the block to which the pixel belongs, for instance, as shown with pixel A, there is a in that the dot position in the pixel will be biased toward the uppermost part. Meanwhile, as shown in FIG. 6, with the image formation device of this embodiment, since the pixel is divided each ⅓ cycle and exposed, it is possible to evenly distribute the dots in each pixel, and it is thereby possible to form a high quality image on the medium.

Moreover, as shown in FIG. 7, with the comparative example, since the dot position in the secondary scanning direction in the pixel is set forth based on the exposure order of the block to which the pixel belongs, there is a problem in that the dot position in the pixel cannot be controlled. Meanwhile, as shown with pixel B and pixel C in FIG. 6, with the image formation device of this embodiment, since it is possible to control the dot in the pixel to a desired position, in particular, smoothing processing of shaded portions and curved portions of the image can be facilitated. As a result, it will be possible to form an even higher quality image on the medium.

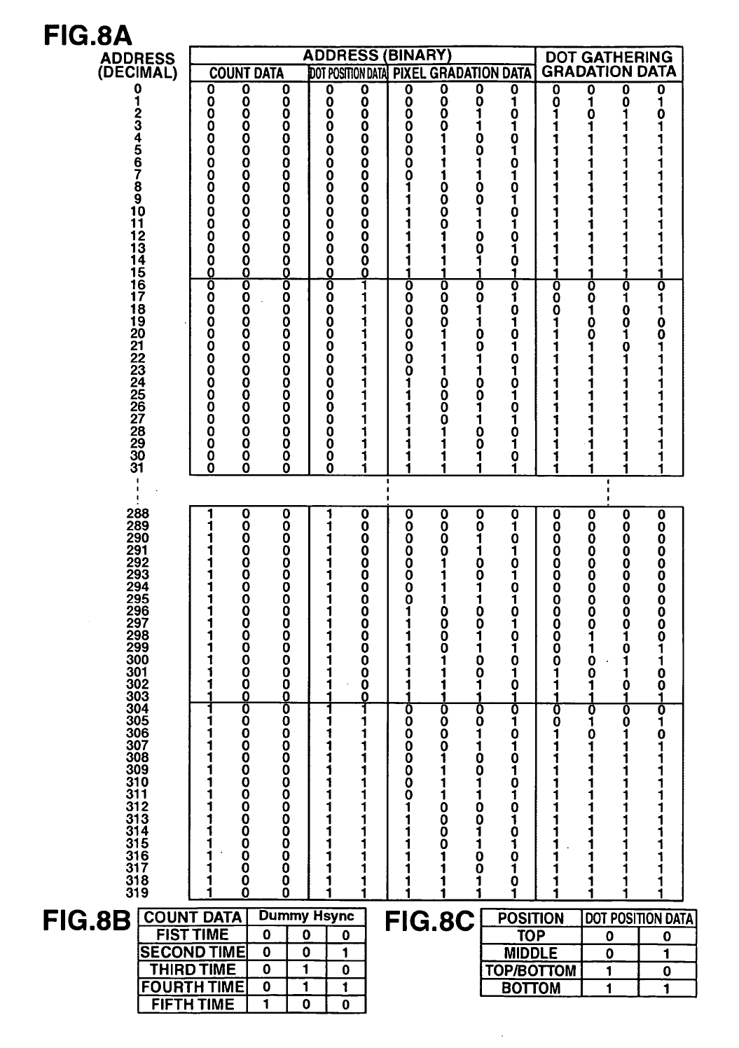

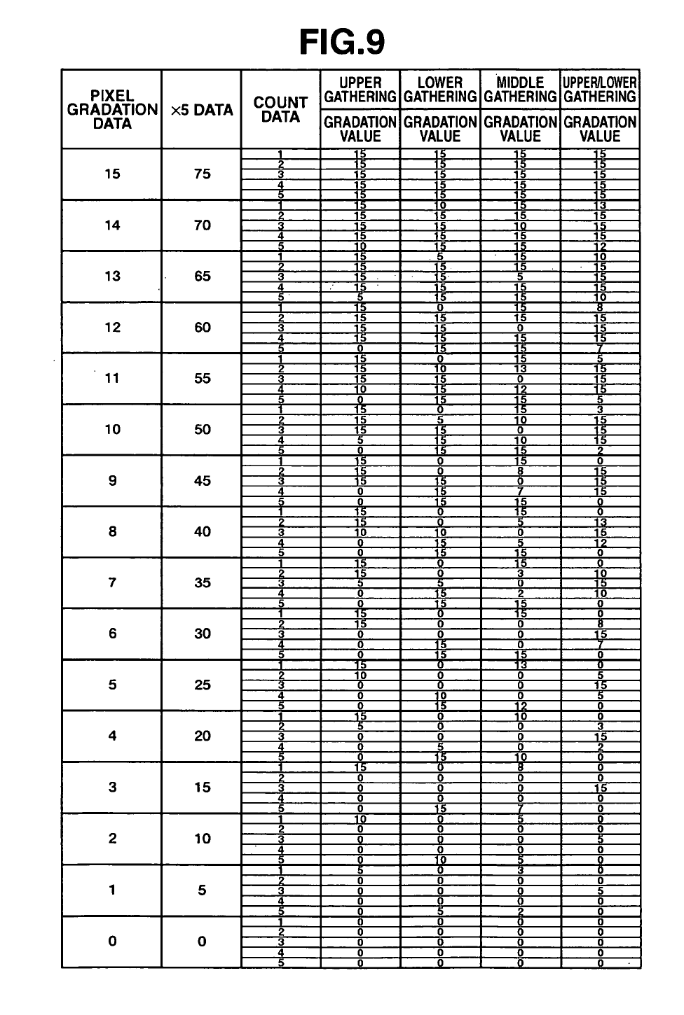

FIG. 8A to FIG. 8C are diagrams showing another example of the data organization of the gradation value LUT 126. Further, FIG. 9 is a diagram showing the setting method of gradation value of the area configuring the pixels in the example illustrated in FIG. 8A to FIG. 8C.

In the image formation device of this embodiment, the number of areas in which the respective pixels are divided is arbitrary. When exposing each pixel upon dividing it into N (N is an integral number of 2 or greater) areas, the bit count of each data or cycle of signals may be suitably changed according to the number of N.

For instance, as shown in FIG. 8A to FIG. 8C, when expositing each pixel upon dividing it into five areas, the DHsync signal is made to be ⅕ cycle of the Hsync signal, and the bit count of the counter 122 is set to 3 bit. Further, as with the setting method explained with reference to FIG. 4, the address and area gradation data to be stored in the gradation value LUT 126 may be set as shown in FIG. 9.

The examples and applications explained through the embodiments of the invention described above may be suitably combined, modified or improved in accordance with the usage thereof, and the invention is in no way limited by the descriptions of the foregoing embodiments. It is evident from the scope of claims that such combinations, modifications or improvements are covered by the technical scope of the invention.

What is claimed is:

1. An exposure head controller for controlling a plurality of light-emitting elements arranged in a first direction and exposing a plurality of pixels, comprising:
an exposure data generator for generating, based on pixel exposure data for exposing the respective pixels, a plurality of area exposure data for respectively exposing a plurality of areas in which the respective pixels are divided in a second direction intersecting with the first direction; and
an exposure controller for exposing the plurality of pixels by controlling the plurality of light-emitting elements and exposing the plurality of areas based on the area exposure data.

2. The exposure head controller according to claim 1, wherein the pixel exposure data contains pixel gradation data showing the gradation of pixels;
the exposure data generator generates area gradation data showing the gradation of the respective areas as the area exposure data based on the pixel gradation data; and
the exposure controller controls the gradation of the plurality of areas based on the area gradation data.

3. The exposure head controller according to claim 2, wherein the exposure data generator generates the area gradation data further based on dot position data showing the position of dots to be exposed in the respective pixels.

4. The exposure head controller according to claim 2, wherein the exposure data generator has a gradation value table that associates and stores the pixel exposure data and the area exposure data.

5. An image formation device comprising the exposure head controller according to claim 1.
